(19) United States
(12) Patent Application Publication
(10) Pub. No.: US 2006/0291309 A1
(43) Pub. Date: Dec. 28, 2006

(54) Driver circuit, electro-optical device, electronic instrument, and drive method

(75) Inventor: Katsuhiko Maki, Chino-shi (JP)

Correspondence Address: OLIFF & BERRIDGE, PLC, P.O. BOX 19928, ALEXANDRIA, VA, 22320, US

(73) Assignee: Seiko Epson Corporation, Tokyo (JP)

(21) Appl. No.: 11/435,785

(22) Filed: May 18, 2006

(30) Foreign Application Priority Data
Jun. 27, 2005 (JP) 2005-186851

(51) Int. Cl. G11C 7/10; G11C 7/00

(52) U.S. Cl. 365/203; 365/189.05

(57) ABSTRACT

A driver circuit includes a first output buffer BUF₁ which drives a data line of an electro-optical device based on grayscale data, and a first precharge circuit PC₁ which precharges an output line of the first output buffer BUF₁. The first precharge circuit PC₁ supplies a first precharge voltage to the output line in a first precharge period in a drive period. In a second precharge period after the first precharge period, the first precharge circuit PC₁ supplies a high-potential-side power supply voltage, a low-potential-side power supply voltage, or the first precharge voltage to the output line based on higher-order two-bit data of the grayscale data. The first output buffer BUF₁ drives the output line based on a grayscale voltage corresponding to the grayscale data after the second precharge period.

Japanese Patent Application No. 2005-186851 filed on Jun. 27, 2005, is hereby incorporated by reference in its entirety.

### BACKGROUND OF THE INVENTION

The present invention relates to a driver circuit, an electro-optical device, an electronic instrument, and a drive method.

A precharge technology has been known which increases the liquid crystal drive speed of an active matrix type liquid crystal display device (liquid crystal device or display device in a broad sense). In this precharge technology, a data line is precharged to a specific potential before driving the data line based on grayscale data, thereby reducing the amount of charging/discharging of the data line due to the supply of a drive voltage based on the grayscale data.

The precharge technology is disclosed in JP-A-10-11032, for example. In JP-A-10-11032, different direct-current potentials are provided in advance, and a switch is provided between each direct-current potential and the data line. The connection between the direct-current potential and the data line is controlled by controlling the switch corresponding to the polarity of the liquid crystal inversion drive. According to this precharge technology, the amount of charging/discharging of the data line along with the drive is small even if the precharge cycle is reduced, whereby an increase in power consumption can be prevented and an accurate voltage can be supplied to the data line.

As the potential of the data line set based on the grayscale voltage corresponding to the grayscale data is closer to the precharge potential, the amount of electric charge which must be charged/discharged by an operational amplifier which drives the data line decreases. Moreover, since the charge/discharge time also decreases, it is possible to deal with a situation in which the drive period (e.g. horizontal scan period) becomes shorter due to an increase in resolution and the like.

However, if the types of precharge potentials are limited to two potentials on the high potential side and the low potential side, the difference between the potential at which the data line is set based on the grayscale voltage and the precharge potential increases, whereby the amount of electric charge which must be charged/discharged by the operational amplifier increases. Moreover, the charge/discharge time also increases. This hinders a further reduction in power consumption and makes it impossible to deal with an increase in resolution.

### SUMMARY

A first aspect of the invention relates to a driver circuit for driving a data line of an electro-optical device, the driver circuit comprising:

an output buffer which drives the data line based on grayscale data; and

a precharge circuit which precharges an output line of the output buffer electrically connected with the data line;

the precharge circuit supplying a first precharge voltage between a high-potential-side power supply voltage and a low-potential-side power supply voltage of the output buffer to the output line in a first precharge period in a drive period;

the precharge circuit supplying the high-potential-side power supply voltage of the output buffer, the low-potential-side power supply voltage of the output buffer, or the first precharge voltage to the output line based on higher-order two-bit data of the grayscale data in a second precharge period after the first precharge period; and

the output buffer driving the output line based on a grayscale voltage corresponding to the grayscale data after the second precharge period.

A second aspect of the invention relates to a driver circuit for driving data lines of an electro-optical device, the driver circuit comprising:

first to Pth (P is an integer of two or more) output buffers which drive the data lines based on grayscale data;

first to Pth precharge circuits which precharge output lines of the output buffers electrically connected with the data lines; and

first to (P-1)th switch devices which electrically connect the output lines of the first to Pth output buffers;

the first to Pth precharge circuits precharging the output lines of the first to Pth output buffers by electrically connecting the output lines of the first to Pth output buffers through the first to (P-1)th switch devices, and the first to Pth output buffers then driving the data lines based on the grayscale data.

A third aspect of the invention relates to an electro-optical device comprising:

a plurality of scan lines;

a plurality of data lines;

a plurality of pixels;

a scan line driver circuit which scans the scan lines; and

the above driver circuit which drives the data lines.

A fourth aspect of the invention relates to an electronic instrument comprising the above electro-optical device.

A fifth aspect of the invention relates to a drive method for driving a data line of an electro-optical device, the method comprising:

supplying a first precharge voltage to an output line of an output buffer for driving the data line in a first precharge period in a drive period;

supplying a high-potential-side power supply voltage of the output buffer, a low-potential-side power supply voltage of the output buffer, or the first precharge voltage to the output line based on higher-order two-bit data of grayscale data in a second precharge period after the first precharge period; and

causing the output buffer to drive the output line based on a grayscale voltage corresponding to the grayscale data after the second precharge period.

A sixth aspect of the invention relates to a drive method for driving a driver circuit including first to Pth (P is an integer of two or more) output buffers which drive data lines of an electro-optical device based on grayscale data, first to Pth precharge circuits which precharge output lines of the output buffers electrically connected with the data lines, and first to (P-1)th switch devices which electrically connect the output lines of the first to Pth output buffers, the method comprising:

in a first precharge period in a drive period, causing at least one of the first to Pth precharge circuits to supply a high-potential-side power supply voltage of the first to Pth output buffers to the output line of the output buffer, causing the remaining precharge circuits to supply a low-potential-side power supply voltage of the first to Pth output buffers to the output lines of the output buffers, and then setting the first to (P-1)th switch devices in a conducting state to set voltages of the output lines of the first to Pth output buffers at a first precharge voltage;

in a second precharge period after the first precharge period, causing the first to Pth precharge circuits to supply the high-potential-side power supply voltage, the low-potential-side power supply voltage, or the first precharge voltage to the output lines of the first to Pth output buffers based on higher-order two-bit data of the grayscale data; and

causing the first to Pth output buffers to drive the output lines based on the grayscale data after the second precharge period.

### BRIEF DESCRIPTION OF THE SEVERAL VIEWS OF THE DRAWING

FIG. 1 is a diagram showing a configuration example of a liquid crystal device according to one embodiment of the invention.

FIG. 2 is a block diagram of a configuration example of a data line driver circuit shown in FIG. 1.

FIG. 3 is a block diagram of a configuration example of a scan line driver circuit shown in FIG. 1.

FIG. 4 is a diagram showing a principle configuration of a first output buffer and a first precharge circuit according to one embodiment of the invention.

FIG. 5 is a diagram illustrative of a precharge voltage according to one embodiment of the invention.

FIG. 6 is a diagram showing an example of a voltage waveform of a data line precharged by a precharge method according to a comparative example of one embodiment of the invention.

FIG. 7 is a diagram showing an example of a voltage waveform of a data line precharged by a precharge method according to one embodiment of the invention.

FIG. 8 is a diagram showing the major portion of the configuration of the data line driver circuit according to one embodiment of the invention.

FIGS. 9A and 9B are diagrams illustrative of an operation for generating a precharge voltage in FIG. 8.

FIG. 10 is a diagram showing the major portion of the configuration of the data line driver circuit when P is “2” in FIG. 8.

FIGS. 11A and 11B are diagrams illustrative of an operation for generating a precharge voltage in FIG. 10.

FIG. 12 is a circuit diagram of a configuration example of the first precharge circuit which realizes the precharge operation shown in FIGS. 10, 11A, and 11B.

FIG. 13 is a timing diagram of an operation example of the circuit diagram shown in FIG. 12.

FIG. 14 is a block diagram of a configuration example of an electronic instrument according to one embodiment of the invention.

### DETAILED DESCRIPTION OF THE EMBODIMENT

The invention may provide a driver circuit suitable for driving a data line at a low power consumption, an electro-optical device, an electronic instrument, and a drive method.

The invention may also provide a driver circuit suitable for driving data lines of an electro-optical device which achieve high resolution at a low power consumption, an electro-optical device, an electronic instrument, and a drive method.

One embodiment of the invention relates to a driver circuit for driving a data line of an electro-optical device, the driver circuit comprising:

an output buffer which drives the data line based on grayscale data; and

a precharge circuit which precharges an output line of the output buffer electrically connected with the data line;

the precharge circuit supplying a first precharge voltage between a high-potential-side power supply voltage and a low-potential-side power supply voltage of the output buffer to the output line in a first precharge period in a drive period;

the precharge circuit supplying the high-potential-side power supply voltage of the output buffer, the low-potential-side power supply voltage of the output buffer, or the first precharge voltage to the output line based on higher-order two-bit data of the grayscale data in a second precharge period after the first precharge period; and

the output buffer driving the output line based on a grayscale voltage corresponding to the grayscale data after the second precharge period.

According to this embodiment, three voltages including the high-potential-side power supply voltage of the output buffer, the low-potential-side power supply voltage of the output buffer, and the first precharge voltage between the high-potential-side power supply voltage and the low-potential-side power supply voltage are provided, and the output line of the output buffer is precharged to one of the three voltages before driving the output line. In more detail, the output line is precharged to the first precharge voltage, and then precharged to one of the three voltages based to the higher-order two-bit data of the grayscale data. The output buffer then drives the output line based on the grayscale voltage. This allows the potential difference driven by the output buffer to be reduced when the output buffer drives the output line in comparison with the case of precharging the output line using two voltages. Therefore, the amount of electric charge which must be charged/discharged by the output buffer can be reduced, whereby the power consumption of the output buffer can be reduced.

In the driver circuit according to this embodiment, the first precharge voltage may be generated as an average value using the voltage to which the output line of the output buffer is precharged and a precharge voltage to which an output line of an output buffer other than the output buffer is precharged.

According to this embodiment, a driver circuit can be provided which contributes to a reduction in the circuit scale of a power supply circuit which generates the power supply voltages.

Another embodiment of the invention relates to a driver circuit for driving data lines of an electro-optical device, the driver circuit comprising:

first to Pth (P is an integer of two or more) output buffers which drive the data lines based on grayscale data;

first to Pth precharge circuits which precharge output lines of the output buffers electrically connected with the data lines; and

first to (P-1)th switch devices which electrically connect the output lines of the first to Pth output buffers;

the first to Pth precharge circuits precharging the output lines of the first to Pth output buffers by electrically connecting the output lines of the first to Pth output buffers through the first to (P-1)th switch devices, and the first to Pth output buffers then driving the data lines based on the grayscale data.

According to this embodiment, before driving the output line of the output buffer, the output line is precharged to the high-potential-side power supply voltage of the output buffer, the low-potential-side power supply voltage of the output buffer, or a given precharge voltage which can be generated by connecting the output lines of the first to Pth output buffers. This allows the potential difference driven by the output buffer to be reduced when the output buffer drives the output line in comparison with the case of precharging the output line using two voltages. Therefore, the amount of electric charge which must be charged/discharged by the output buffer can be reduced, whereby the power consumption of the output buffer can be reduced.

In the driver circuit according to this embodiment, in a first precharge period in a drive period, at least one of the first to Pth precharge circuits may supply a high-potential-side power supply voltage of the first to Pth output buffers to the output line of the output buffer, the remaining precharge circuits may supply a low-potential-side power supply voltage of the first to Pth output buffers to the output lines of the output buffers, and the first to (P-1)th switch devices may be then set in a conducting state to set voltages of the output lines of the first to Pth output buffers at a first precharge voltage; in a second precharge period after the first precharge period, the first to Pth precharge circuits may supply the high-potential-side power supply voltage, the low-potential-side power supply voltage, or the first precharge voltage to the output lines of the first to Pth output buffers based on higher-order two-bit data of the grayscale data; and the first to Pth output buffers may drive the output lines based on the grayscale data after the second precharge period.

According to this embodiment, the first precharge voltage is generated by using the high-potential-side and the low-potential-side power supply voltage of the output buffer. This contributes to a reduction in the circuit scale of a power supply circuit and allows generation of the first precharge voltage using a simple configuration. Moreover, the potential difference driven by the output buffer when the output buffer drives the output line can be reduced in comparison with the case of precharging the output line using two voltages. Therefore, the amount of electric charge which must be charged/discharged by the output buffer can be reduced, whereby the power consumption of the output buffer can be reduced.

Another embodiment of the invention relates to an electro-optical device comprising:

a plurality of scan lines;

a plurality of data lines;

a plurality of pixels;

a scan line driver circuit which scans the scan lines; and

the above driver circuit which drives the data lines.

According to this embodiment, an electro-optical device can be provided which includes a driver circuit suitable for driving a data line at a low power consumption. According to this embodiment, an electro-optical device can also be provided which includes a driver circuit suitable for driving data lines which achieve high resolution at a low power consumption.

Another embodiment of the invention relates to an electronic instrument comprising the above electro-optical device.

According to this embodiment, an electronic instrument can be provided to which an electro-optical device, which includes a driver circuit suitable for driving a data line at a low power consumption, is applied. According to this embodiment, an electronic instrument can be provided to which an electro-optical device, which includes a driver circuit suitable for driving data lines which achieve high resolution at a low power consumption, is applied.

Another embodiment of the invention relates to a drive method for driving a data line of an electro-optical device, the method comprising:

supplying a first precharge voltage to an output line of an output buffer for driving the data line in a first precharge period in a drive period;

supplying a high-potential-side power supply voltage of the output buffer, a low-potential-side power supply voltage of the output buffer, or the first precharge voltage to the output line based on higher-order two-bit data of grayscale data in a second precharge period after the first precharge period; and

causing the output buffer to drive the output line based on a grayscale voltage corresponding to the grayscale data after the second precharge period.

A further embodiment of the invention relates to a drive method including first to Pth (P is an integer of two or more) output buffers which drive a driver circuit for driving data lines of an electro-optical device based on grayscale data, first to Pth precharge circuits which precharge output lines of the output buffers electrically connected with the data lines, and first to (P-1)th switch devices which electrically connect the output lines of the first to Pth output buffers, the method comprising:

in a first precharge period in a drive period, causing at least one of the first to Pth precharge circuits to supply a high-potential-side power supply voltage of the first to Pth output buffers to the output line of the output buffer, causing the remaining precharge circuits to supply a low-potential-side power supply voltage of the first to Pth output buffers to the output lines of the output buffers, and then setting the first to (P-1)th switch devices in a conducting state to set voltages of the output lines of the first to Pth output buffers at a first precharge voltage;

in a second precharge period after the first precharge period, causing the first to Pth precharge circuits to supply the high-potential-side power supply voltage, the low-potential-side power supply voltage, or the first precharge voltage to the output lines of the first to Pth output buffers based on higher-order two-bit data of the grayscale data; and

causing the first to Pth output buffers to drive the output lines based on the grayscale data after the second precharge period.

The embodiments of the invention are described below in detail with reference to the drawings. Note that the embodiments described below do not in any way limit the scope of the invention laid out in the claims. Note that all elements of the embodiments described below should not necessarily be taken as essential requirements for the invention.

1. Liquid Crystal Device

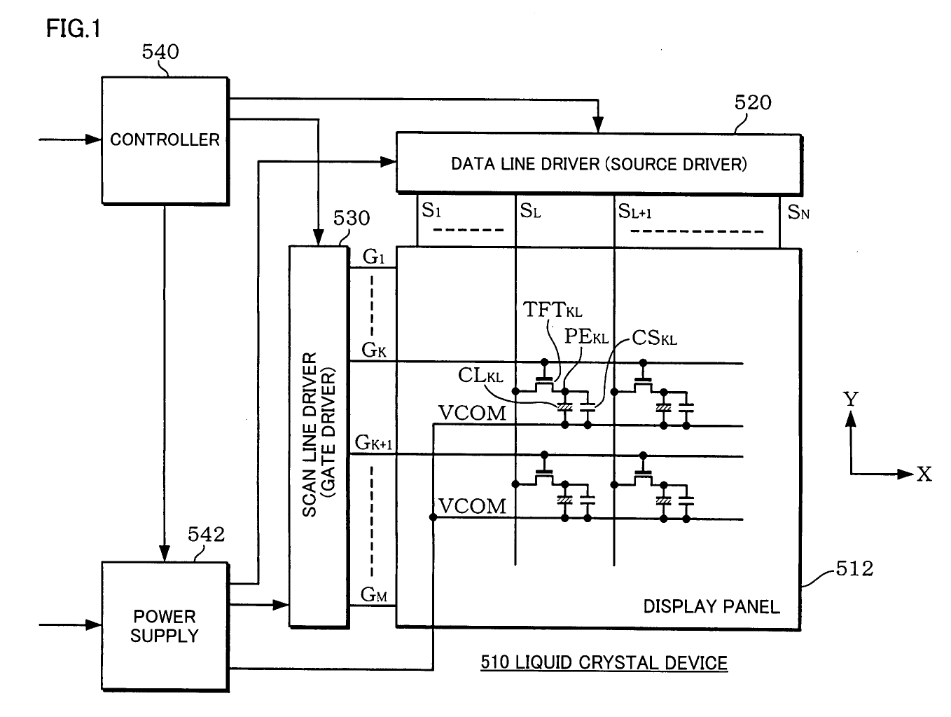

FIG. 1 shows an example of a block diagram of a liquid crystal device to which an operational amplifier according to one embodiment of the invention is applied.

A liquid crystal device 510 (display device in a broad sense) includes a display panel 512 (liquid crystal display (LCD) panel in a narrow sense), a data line driver circuit 520 (source driver in a narrow sense), a scan line driver circuit 530 (gate driver in a narrow sense), a controller 540, and a power supply circuit 542. The liquid crystal device 510 need not necessarily include all of these circuit blocks. The liquid crystal device 510 may have a configuration in which at least one of these circuit blocks is omitted.

The display panel 512 (electro-optical device in a broad sense) includes a plurality of scan lines (gate lines in a narrow sense), a plurality of data lines (source lines in a narrow sense), and pixels (pixel electrodes) specified by the scan lines and the data lines. In this case, an active matrix type liquid crystal device may be formed by connecting a thin film transistor (TFT; switching device in a broad sense) with the data line and connecting the pixel electrode with the thin film transistor TFT.

In more detail, the display panel 512 is formed on an active matrix substrate (e.g. glass substrate). A plurality of scan lines G₁ to G_{M} (M is a positive integer of two or more), arranged in a direction Y shown in FIG. 1 and extending in a direction X, and a plurality of data lines S₁ to S_{N} (N is a positive integer of two or more), arranged in the direction X and extending in the direction Y, are disposed on the active matrix substrate. A thin film transistor TFT_{KL} (switching device in a broad sense) is provided at a position corresponding to the intersecting point of the scan line G_{K} (1≦K≦M, K is a positive integer) and the data line S_{L} (1≦L≦N, L is a positive integer).

A gate electrode of the thin film transistor TFT_{KL} is connected with the scan line G_{K}, a source electrode of the thin film transistor TFT_{KL} is connected with the data line S_{L}, and a drain electrode of the thin film transistor TFT_{KL} is connected with a pixel electrode PE_{KL}. A liquid crystal capacitor CL_{KL} (liquid crystal element) and a storage capacitor CS_{KL} are formed between the pixel electrode PE_{KL} and a common electrode VCOM which faces the pixel electrode PE_{KL} through a liquid crystal element (electro-optical substance in a broad sense). A liquid crystal is sealed between the active matrix substrate, on which the thin film transistor TFT_{KL}, the pixel electrode PE_{KL}, and the like are formed, and a common substrate on which the common electrode VCOM is formed. The transmissivity of the pixel changes corresponding to the voltage applied between the pixel electrode PE_{KL} and the common electrode VCOM.

A voltage applied to the common electrode VCOM is generated by the power supply circuit 542. The common electrode VCOM may be formed in a stripe pattern corresponding to each scan line instead of forming the common electrode VCOM over the common substrate.

The data line driver circuit 520 drives the data lines S₁ to S_{N} of the display panel 512 based on grayscale data. The scan line driver circuit 530 sequentially scans the scan lines G₁ to G_{M} of the display panel 512.

The controller 540 controls the data line driver circuit 520, the scan line driver circuit 530, and the power supply circuit 542 according to information set by a host such as a central processing unit (CPU) (not shown).

In more detail, the controller 540 sets an operation mode or supplies a vertical synchronization signal or a horizontal synchronization signal generated therein to the data line driver circuit 520 and the scan line driver circuit 530, and controls the polarity reversal timing of the voltage of the common electrode VCOM for the power supply circuit 542, for example.

The power supply circuit 542 generates various voltages (grayscale voltage) necessary for driving the display panel 512 and the voltage of the common electrode VCOM based on a reference voltage supplied from the outside.

In FIG. 1, the liquid crystal device 510 includes the controller 540. Note that the controller 540 may be provided outside the liquid crystal device 510. Or, the host may be included in the liquid crystal device 510 together with the controller 540. At least one or all of the data line driver circuit 520, the scan line driver circuit 530, the controller 540, and the power supply circuit 542 may be formed on the display panel 512. The liquid crystal device 510 or the display panel 512 may be incorporated into various electronic instruments such as a portable telephone, portable information instrument (e.g. PDA), digital camera, projector, portable audio player, mass storage device, video camera, electronic notebook, or global positioning system (GPS).

1.1 Data Line Driver Circuit

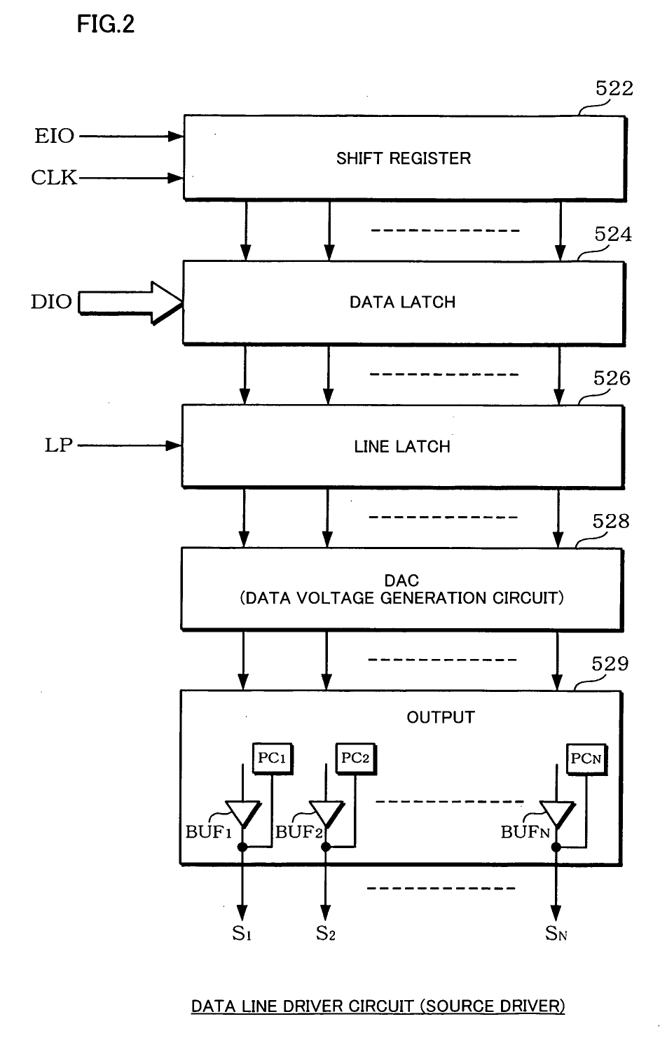

FIG. 2 shows a configuration example of the data line driver circuit 520 shown in FIG. 1.

The data line driver circuit 520 (driver circuit in a broad sense) includes a shift register 522, a data latch 524, a line latch 526, a reference voltage generation circuit 527, a DAC 528 (digital-analog conversion circuit; data voltage generation circuit in a broad sense), and an output circuit 529.

The shift register 522 includes a plurality of flip-flops provided in data line units and sequentially connected. The shift register 522 holds an enable input-output signal EIO in synchronization with a clock signal CLK, and sequentially shifts the enable input-output signal EIO to the adjacent flip-flops in synchronization with the clock signal CLK.

Grayscale data (DIO) is input to the data latch 524 from the controller 540 in units of 18 bits (6 bits (data of each color component)×3 (each color of RGB)), for example. The data latch 524 latches the grayscale data (DIO) in synchronization with the enable input-output signal EIO sequentially shifted by the flip-flops of the shift register 522.

The line latch 526 latches the grayscale data in horizontal scan units latched by the data latch 524 in synchronization with a horizontal synchronization signal LP supplied from the controller 540.

The reference voltage generation circuit 527 generates reference voltages in units of 64 (=2⁶) grayscales indicated by six-bit grayscale data. In more detail, the reference voltage generation circuit 527 shown in FIG. 2 selects 64 reference voltages from 256 voltages generated by dividing the voltage between high-potential-side and low-potential-side power supply voltages supplied from the power supply circuit 542, and outputs the selected reference voltages as the grayscale voltages.

The DAC 528 generates an analog data voltage supplied to each data line. In more detail, the DAC 528 selects one of the grayscale voltages from the power supply circuit 542 shown in FIG. 1 based on the digital grayscale data from the line latch 526, and outputs an analog data voltage corresponding to the digital grayscale data.

The output circuit 529 buffers the data voltage from the DAC 528, and drives the data line by outputting the data voltage to the data line. In more detail, the output circuit 529 includes first to Nth output buffers BUF₁ to BUF_{N} provided in data line units, and first to Nth precharge circuits PC₁ to PC_{N} provided in output buffer units. Each of the first to Nth output buffers BUF₁ to BUF_{N} may be formed by a voltage-follower-connected operational amplifier, for example. In this case, the operational amplifier performs impedance conversion of the data voltage from the DAC 528, and outputs the converted data voltage to the data line.

Each of the first to Nth precharge circuits PC₁ to PC_{N} precharges the output line to which the output buffer outputs the drive voltage before each of the first to Nth output buffers BUF₁ to BUF_{N} drives the data line. After precharging, each of the first to Nth output buffers BUF₁ to BUF_{N} drives the precharged output line based on the grayscale voltage corresponding to the data line.

In FIG. 2, the digital grayscale data is subjected to digital-analog conversion and output to the data line through the output circuit 529. Note that an analog image signal may be sampled, held, and output to the data line through the output circuit 529.

1.2 Scan line Driver Circuit

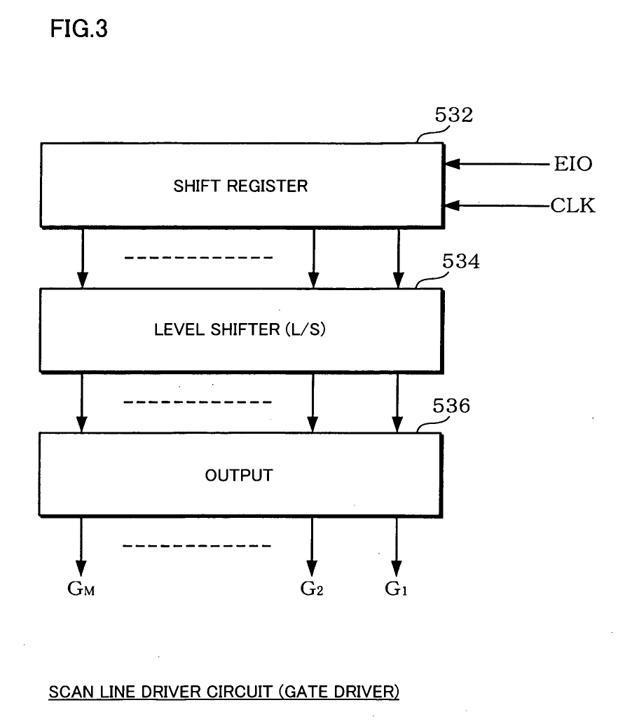

FIG. 3 shows a configuration example of the scan line driver circuit 530 shown in FIG. 1.

The scan line driver circuit 530 includes a shift register 532, a level shifter 534, and an output circuit 536.

The shift register 532 includes a plurality of flip-flops provided corresponding to the scan lines and sequentially connected. The shift register 532 holds the enable input-output signal EIO in the flip-flop in synchronization with the clock signal CLK, and sequentially shifts the enable input-output signal EIO to the adjacent flip-flops in synchronization with the clock signal CLK. The enable input-output signal EIO input to the shift register 532 is a vertical synchronization signal supplied from the controller 540.

The level shifter 534 shifts the level of the voltage from the shift register 532 to the voltage level corresponding to the liquid crystal element of the display panel 512 and the transistor performance of the thin film transistor TFT. As the voltage level, a high voltage level of 20 to 50 V is necessary, for example.

The output circuit 536 buffers the scan voltage shifted by the level shifter 534, and drives the scan line by outputting the scan voltage to the scan line.

2. Precharge Method According to this Embodiment

A precharge method according to this embodiment is described below.

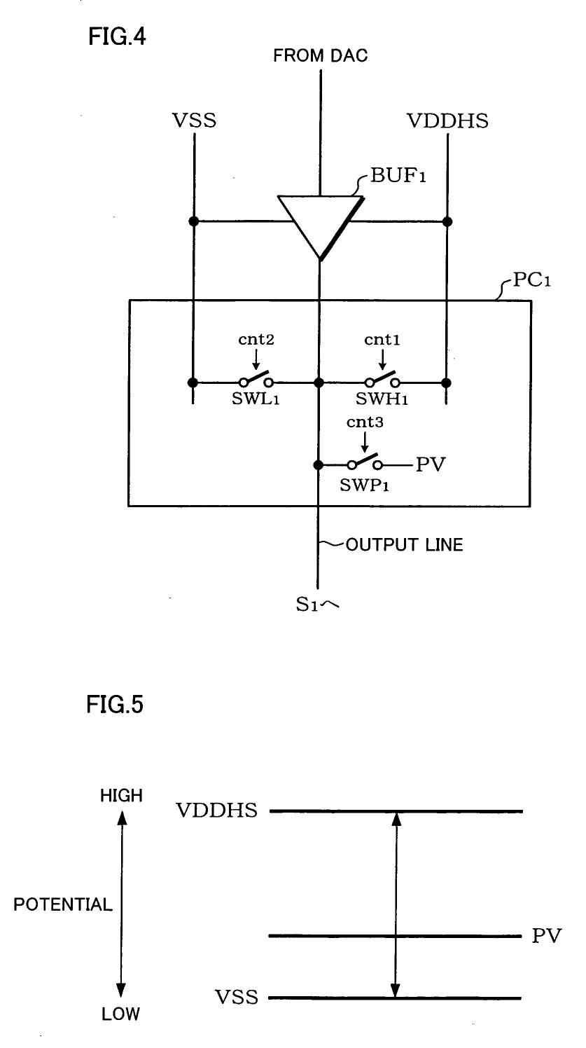

FIG. 4 shows a principle configuration of the first output buffer BUF₁ and the first precharge circuit PC₁ according to this embodiment. Although FIG. 4 shows the configuration of the first output buffer BUF₁ and the first precharge circuit PC₁, the principle configuration of other output buffers and precharge circuits is the same as shown in FIG. 4.

A high-potential-side power supply voltage VDDHS and a low-potential-side power supply voltage VSS are supplied to the first output buffer BUF₁. The first output buffer BUF₁ outputs the voltage between the high-potential-side power supply voltage and the low-potential-side power supply voltage to the output line.

The first precharge circuit PC₁ includes precharge switch devices SWH₁, SWL₁, and SWP₁. The high-potential-side power supply voltage VDDHS of the first output buffer BUF₁ can be supplied to the output line of the first output buffer BUF₁ through the precharge switch device SWH₁ based on a switch control signal cnt1. The low-potential-side power supply voltage VSS of the first output buffer BUF₁ can be supplied to the output line of the first output buffer BUF₁ through the precharge switch device SWL₁ based on a switch control signal cnt2. A precharge voltage PV (first precharge voltage) can be supplied to the output line of the first output buffer BUF₁ through the precharge switch device SWP₁ based on a switch control signal cnt3. For example, a control section (not shown) provided in the data line driver circuit 520 includes a control register in which a value is set by the host or the controller 540. The control section (or precharge control circuit (not shown)) generates the switch control signals cnt1, cnt2, and cnt3 so that the switch control signals cnt1, cnt2, and cnt3 change at a timing corresponding to the value set in the control register.

FIG. 5 is a diagram illustrative of the precharge voltage PV according to this embodiment.

As shown in FIG. 5, the potential of the precharge voltage PV is lower than the potential of the high-potential-side power supply voltage VDDHS and is higher than the potential of the low-potential-side power supply voltage VSS. The precharge voltage PV may be generated by the power supply circuit 542. However, it is preferable to generate the precharge voltage PV using the high-potential-side power supply voltage VDDHS and the low-potential-side power supply voltage VSS in order to reduce the circuit scale of the power supply circuit 542.

A precharge method according to a comparative example of this embodiment is described below before describing the precharge method according to this embodiment.

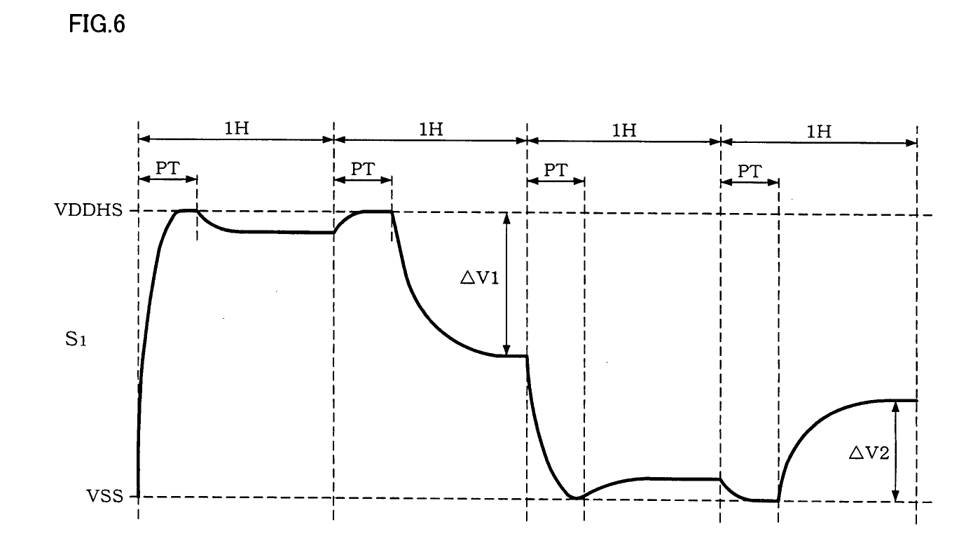

FIG. 6 shows an example of the voltage waveform of the data line S₁ precharged by the precharge method according to the comparative example of this embodiment.

In the comparative example, the high-potential-side power supply voltage VDDHS and the low-potential-side power supply voltage VSS of the output buffer are used as the voltages for precharging the output line of the output buffer. When it is determined that the data line S₁ is driven toward the high potential side based on the grayscale voltage in the horizontal scan period (1H) (drive period in a broad sense), the data line S₁ is precharged to the high-potential-side power supply voltage VDDHS in a precharge period PT in the horizontal scan period. After the precharge period PT, the data line S₁ is driven based on the grayscale voltage.

On the other hand, when it is determined that the data line S₁ is driven toward the low potential side based on the grayscale voltage in the horizontal scan period, the data line S₁ is precharged to the low-potential-side power supply voltage VSS in the precharge period PT in the horizontal scan period. After the precharge period PT, the data line S₁ is driven based on the grayscale voltage.

In this embodiment, the precharge voltage PV is provided between the high-potential-side power supply voltage and the low-potential-side power supply voltage of the first output buffer BUF₁ so that the difference between the potential of the output line driven by the first output buffer BUF₁ based on the grayscale voltage and the precharge potential becomes smaller. In this embodiment, the range of the potential at which the first output buffer BUF₁ drives the output line based on the grayscale voltage is divided into three areas, and the precharge potential is changed corresponding to each area. In more detail, the output line of the first output buffer BUF₁ is set at the precharge voltage PV, and then precharged to the potential corresponding to the higher-order two-bit data of the grayscale data.

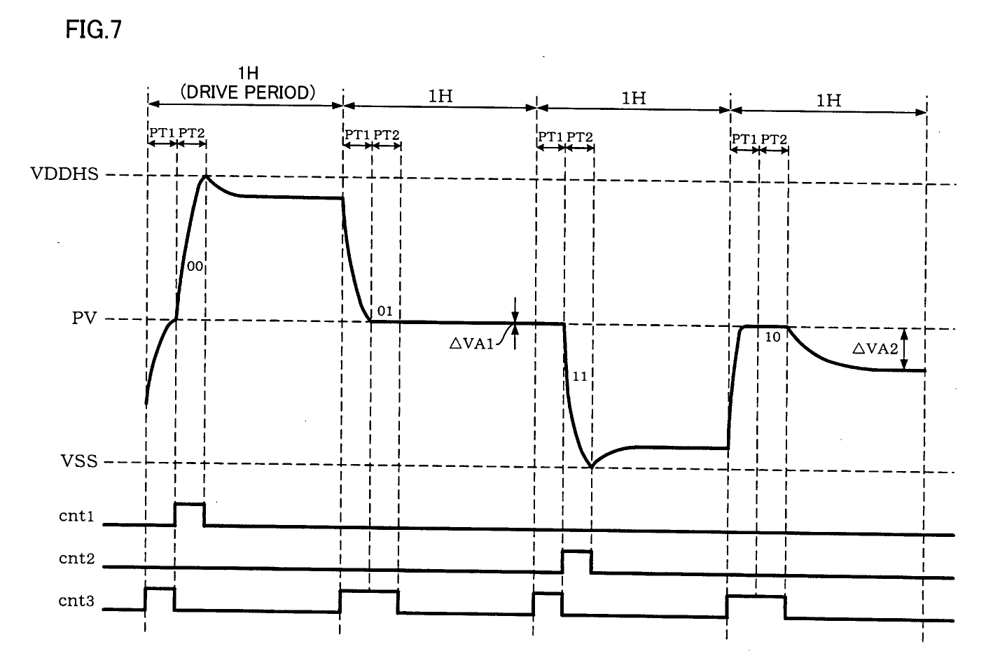

FIG. 7 shows an example of the voltage waveform of the data line S₁ precharged by the precharge method according to this embodiment. In FIGS. 6 and 7, the output buffer drives the output line based on an identical grayscale voltage in each horizontal scan period 1H. In FIG. 7, the precharge method according to this embodiment is realized using the configuration shown in FIG. 4.

The following description is given on the assumption that the potential of the grayscale voltage increases as the grayscale value corresponding to the grayscale data becomes larger and the potential of the grayscale voltage decreases as the grayscale value becomes smaller. Note that the invention is not limited thereto. The invention may also be applied to the case where the potential of the grayscale voltage decreases as the grayscale value corresponding to the grayscale data becomes larger and the potential of the grayscale voltage increases as the grayscale value becomes smaller.

The precharge switch devices SWH₁, SWL₁, and SWP₁ are set in a nonconducting state at the start of the horizontal scan period (drive period; 1H). In this embodiment, in a first precharge period PT1 in the horizontal scan period 1H, the first precharge circuit PC₁ supplies the precharge voltage PV to the output line of the first output buffer BUF₁ as the first precharge voltage. Specifically, in the first precharge period PT1, the switch control signal cnt3 changes to the H level so that the precharge switch device SWP₁ is set in a conducting state, and the precharge switch devices SWH₁ and SWL₁ remain in a nonconducting state.

In a second precharge period PT2 after the first precharge period PT1, the first precharge circuit PC₁ supplies the high-potential-side power supply voltage VDDHS of the first output buffer BUF₁, the low-potential-side power supply voltage VSS of the first output buffer BUF₁, or the precharge voltage PV (first precharge voltage) to the output line based on the higher-order two-bit data of the grayscale data in the horizontal scan period 1H.

For example, when the grayscale data is six bits, the grayscale value ranges from “0” to “63”. When the higher-order two-bit data of the grayscale data is “11” (i.e. when the grayscale value is in the range of “48” to “63”), the output line of the first output buffer BUF₁ is precharged to the low-potential-side power supply voltage VSS in the second precharge period PT2. When the higher-order two-bit data of the grayscale data is “01” or “10” (i.e. when the grayscale value is in the range of “16” to “47”), the output line of the first output buffer BUF₁ is precharged to the precharge voltage PV in the second precharge period PT2. When the higher-order two-bit data of the grayscale data is “00” (i.e. when the grayscale value is in the range of “0” to “15”), the output line of the first output buffer BUF₁ is precharged to the high-potential-side power supply voltage VDDHS in the second precharge period PT2.

After the second precharge period PT2, the first output buffer BUF₁ drives the output line based on the grayscale voltage corresponding to the grayscale data.

In FIG. 7, since the higher-order two-bit data of the grayscale data is “00” in the second precharge period PT2 in the first horizontal scan period 1H, the switch control signal cnt1 changes to the H level so that the output line of the first output buffer BUF₁ is precharged to the high-potential-side power supply voltage VDDHS. Since the higher-order two-bit data of the grayscale data is “01” in the second precharge period PT2 in the next horizontal scan period 1H, the switch control signal cnt3 changes to the H level so that the output line of the first output buffer BUF₁ is precharged to the precharge voltage PV. Since the higher-order two-bit data of the grayscale data is “11” in the second precharge period PT2 in the next horizontal scan period 1H, the switch control signal cnt2 changes to the H level so that the output line of the first output buffer BUF₁ is precharged to the low-potential-side power supply voltage VSS. Since the higher-order two-bit data of the grayscale data is “10” in the second precharge period PT2 in the final horizontal scan period 1H, the switch control signal cnt3 changes to the H level so that the output line of the first output buffer BUF₁ is precharged to the precharge voltage PV.

The potential difference corresponding to the amount of electric charge which must be charged/discharged by the output buffer after the precharge period PT in the second horizontal scan period 1H in FIG. 6 is ΔV1, and the potential difference corresponding to the amount of electric charge which must be charged/discharged by the first output buffer BUF₁ after the second precharge period PT2 in the second horizontal scan period 1H in FIG. 7 is ΔVA1. Specifically, the potential difference ΔVA1 is smaller than the potential difference ΔV1. The potential difference corresponding to the amount of electric charge which must be charged/discharged by the output buffer after the precharge period PT in the fourth horizontal scan period 1H in FIG. 6 is ΔV2, and the potential difference corresponding to the amount of electric charge which must be charged/discharged by the first output buffer BUF, after the second precharge period PT2 in the fourth horizontal scan period 1H in FIG. 7 is ΔVA2. Specifically, the potential difference ΔVA2 is smaller than the potential difference ΔV2.

The data line S₁ is driven by the output buffer after the precharge period in FIG. 6 and the second precharge period in FIG. 7. Since the output buffer is provided in data line units, the amount of electric charge which must be charged/discharged is reduced as the potential difference driven by the output buffer after precharging becomes smaller, whereby the power consumption of the output buffer can be reduced. Moreover, when the output buffer is formed by an operational amplifier, the current consumption of the operational amplifier can be reduced as the charge/discharge time becomes shorter.

2.1 Generation of Precharge Voltage

In this embodiment, the precharge voltage PV is generated by using the high-potential-side power supply voltage VDDHS and the low-potential-side power supply voltage VSS. In the configuration shown in FIG. 4, the precharge voltage PV is generated as an average value using the voltage to which the output line of the output buffer is precharged and the precharge voltage to which the output line of another output buffer is precharged, for example.

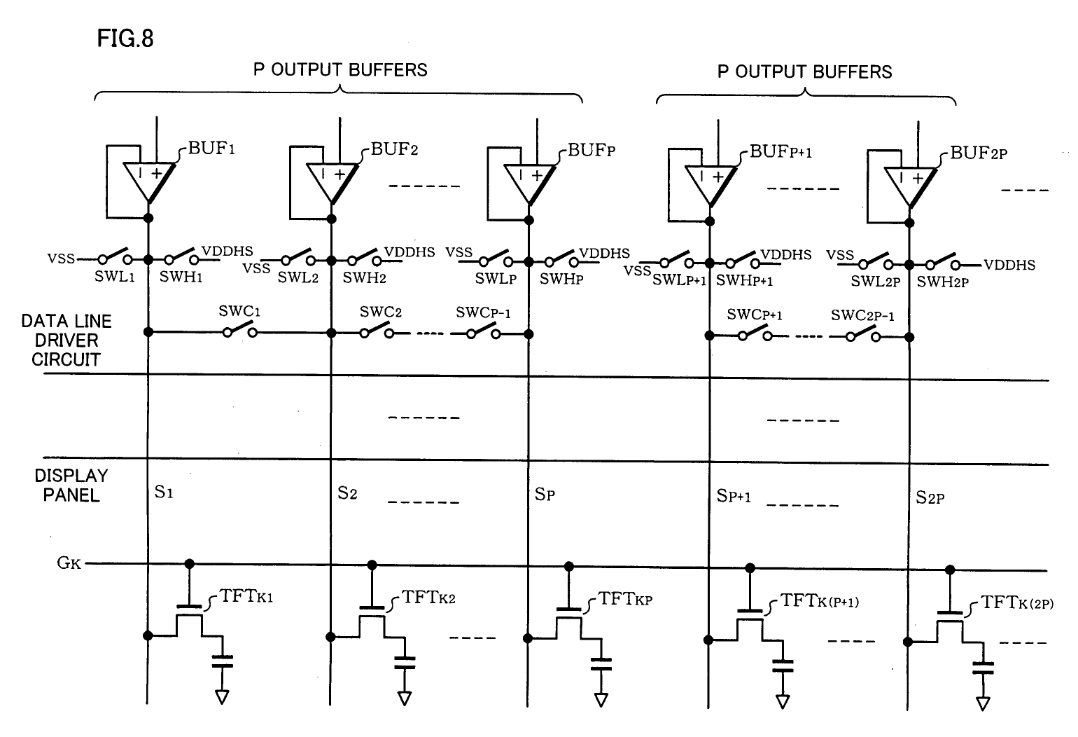

FIG. 8 shows the major portion of the configuration of the data line driver circuit 520 according to this embodiment. In FIG. 8, a voltage-follower-connected operational amplifier is used as the output buffer.

Differing from the configuration shown in FIG. 4 in which the precharge switch device for supplying the precharge voltage to the output line of the output buffer is provided, first to (P-1)th (P is an integer of two or more) switch devices SWC₁ to SWC_{P-1} for electrically connecting the output lines of the output buffers are provided in units of P output buffers.

When the P output buffers make up one group, the configuration of each group is identical. For example, the group which drives the data lines S₁ to S_{P} includes the first to Pth output buffers BUF₁ to BUF_{P}, the first to Pth precharge circuits PC₁ to PC_{P} for precharging the output lines of the output buffers electrically connected with the data lines, and the first to (P-1)th switch devices SWC₁ to SWC_{P-1} for electrically connecting the output lines of the first to Pth output buffers BUF₁ to BUF_{P}.

In FIG. 8, the precharge switch device SWP₁ is omitted from the precharge circuit shown in FIG. 4, and the first switch device SWC₁ is used by the first and second output buffers BUF₁ and BUF₂. The means for supplying the high-potential-side power supply voltage VDDHS and the means for supplying the low-potential-side power supply voltage VSS are merely provided to the output line of each output buffer.

In this embodiment, a common precharge voltage PV can be generated in units of P output buffers by utilizing a parasitic capacitor such as a wiring capacitor of the data line of the display panel 512. The precharge operation shown in FIG. 7 is performed using the precharge voltage PV.

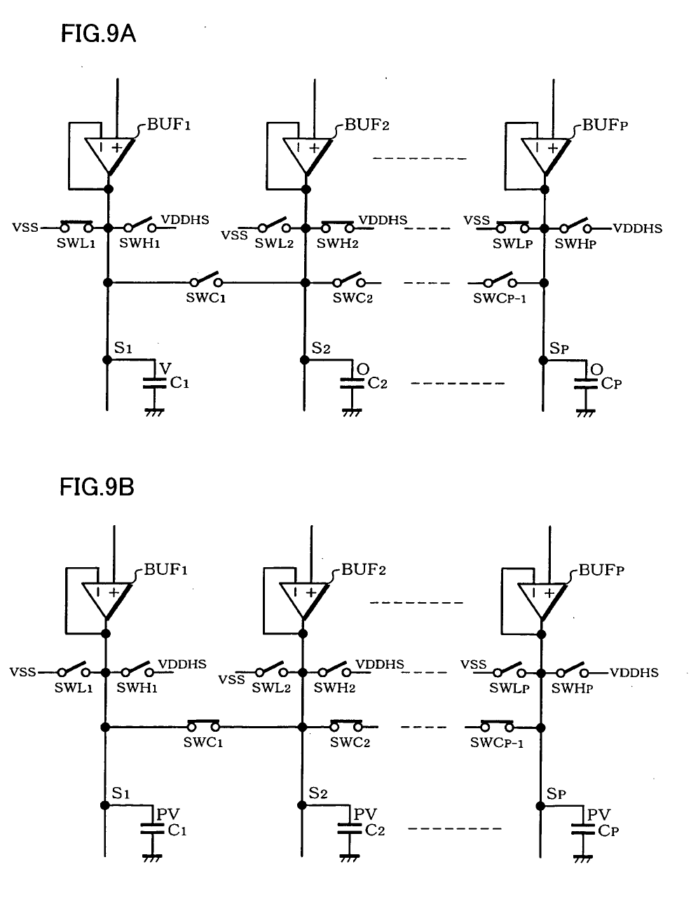

FIGS. 9A and 9B are diagrams illustrative of the operation for generating the precharge voltage PV in FIG. 8.

FIGS. 9A and 9B illustrate the case where the precharge voltage PV is generated for the first to Pth output buffers BUF₁ to BUF_{P}. Note that the precharge voltage PV can be generated in other groups in the same manner as described below.

In each drive period, the precharge voltage is generated according to the procedure shown in FIGS. 9A and 9B in the first precharge period PT1 or before the first precharge period PT1.

A state in which the precharge switch devices SWL₁ to SWL_{P} and SWH₁ to SWH_{P} and the first to (P-1)th switch devices SWC₁ to SWC_{P-1} are set in a nonconducting state transitions to the state shown in FIG. 9A.

In FIG. 9A, the high-potential-side power supply voltage VDDHS is supplied to the output line of at least one of the first to Pth output buffers BUF₁ to BUF_{P} in the first precharge period PT1 in the horizontal scan period 1H (drive period), and the low-potential-side power supply voltage VSS is supplied to the output lines of the remaining output buffers. Therefore, at least one of the first to Pth precharge circuits PC₁ to PC_{P} supplies the high-potential-side power supply voltage VDDHS to the output line of at least one of the first to Pth output buffers BUF₁ to BUF_{P}, and the remaining precharge circuits supply the low-potential-side power supply voltage VSS to the output lines of the remaining output buffers of the first to Pth output buffers BUF₁ to BUF_{P}. In FIG. 9A, at least one of the precharge switch devices SWH₁ to SWH_{P} connected with the output lines of the first to Pth output buffers BUF₁ to BUF_{P} is set in a conducting state, and the precharge switch devices of the precharge switch devices SWL₁ to SWL_{P} connected with the output lines of the remaining output buffers are set in a conducting state. Therefore, the high-potential-side power supply voltage VDDHS or the low-potential-side power supply voltage VSS is supplied to the output line of each output buffer.

As a result, the high-potential-side power supply voltage VDDHS or the low-potential-side power supply voltage VSS of the first to Pth output buffers BUF₁ to BUF_{P} is supplied to the data lines S₁ to S_{P} of the display panel 512 connected with the first to Pth output buffers BUF₁ to BUF_{P}. An electric charge corresponding to the voltage supplied to each data line is stored in a parasitic capacitor such as a wiring capacitor of each data line. In FIG. 9A, an electric charge corresponding to a voltage V is stored in a parasitic capacitor C₁ of the data line S₁ , and a voltage of 0 V is applied to parasitic capacitors C₂ and C_{P} of the data lines S₂ and S_{P}.

Then, the precharge switch devices SWH₁ to SWH_{P} and SWL₁ to SWL_{P} connected with the first to Pth output buffers BUF₁ to BUF_{P} are set in a nonconducting state, and the first to (P-1)th switch devices SWC₁ to SWC_{P-1} are set in a conducting state from a nonconducting state. As a result, the output lines (data lines S₁ to S_{P} ) of the first to Pth output buffers BUF₁ to BUF_{P} are electrically connected. This causes the electric charge stored in the data lines S₁ to S_{P} to be divided among the data lines. Therefore, each data line is set at a voltage corresponding to the amount of electric charge divided and stored in the parasitic capacitor, and this voltage is used as the precharge voltage PV.

When setting the output lines of half of the first to Pth output buffers BUF₁ to BUF_{P} at the high-potential-side power supply voltage VDDHS and setting the output lines of the remaining output buffers at the low-potential-side power supply voltage VSS, the precharge voltage PV is set at a voltage having a potential half the potential of the high-potential-side power supply voltage VDDHS. The potential of the precharge voltage PV can be changed by changing the number of output buffers of the first to Pth output buffers BUF₁ to BUF_{P} of which the output line is set at the high-potential-side power supply voltage VDDHS (low-potential-side power supply voltage VSS).

Then, the precharge switch devices SWL₁ to SWL_{P} and SWH₁ to SWH_{P} and the first to (P-1)th switch devices SWC₁ to SWC_{P-1} are set in a nonconducting state, and the precharge operation corresponding to the higher-order two-bit data of the grayscale data is performed as described above using the voltage of the data line as the precharge voltage PV.

The voltage of each data line when electrically connecting the output lines of the first to Pth output buffers BUF₁ to BUF_{P} through the first to (P-1)th switch devices SWC₁ to SWC_{P-1} without supplying the high-potential-side power supply voltage VDDHS or the low-potential-side power supply voltage VSS to each data line may be used as the precharge voltage, and the first to Pth precharge circuits may precharge the output lines of the first to Pth output buffers BUF₁ to BUF_{P} corresponding to the higher-order two-bit data of the grayscale data as described above.

The case where P is “2” is described below in detail.

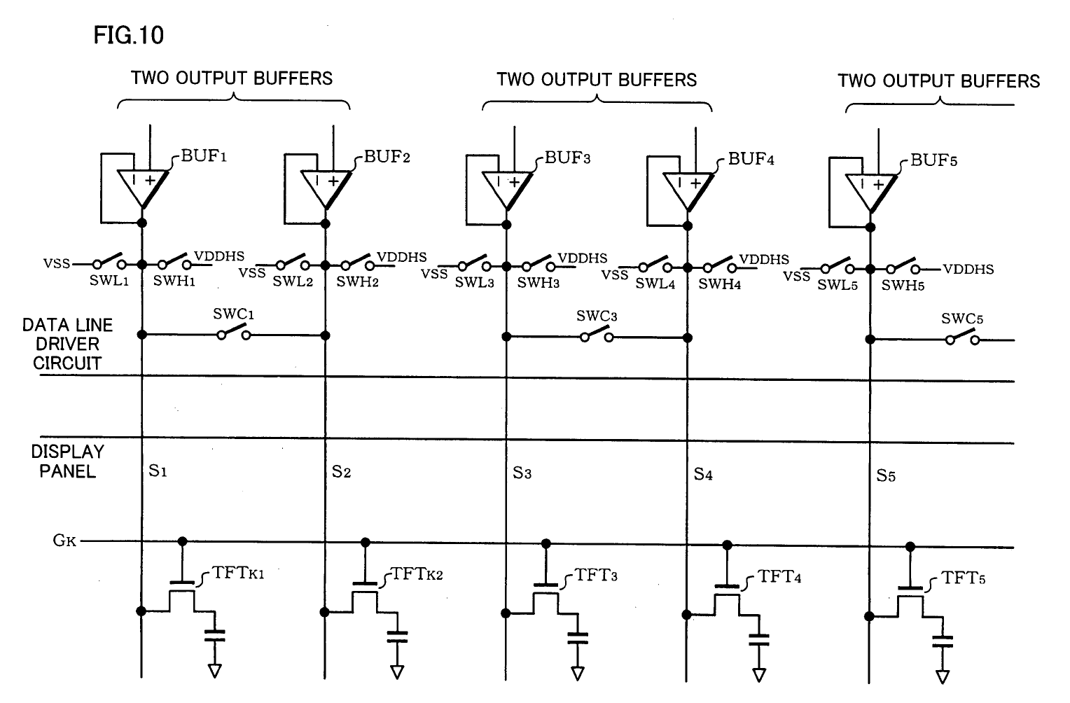

FIG. 10 shows the major portion of the configuration of the data line driver circuit 520 when P is “2” in FIG. 8.

As shown in FIG. 10, the switch device which electrically connects the output lines of the output buffers is provided in units of two output buffers.

Two output buffers make up one group, and the configuration of each group is identical. For example, the group which drives the data lines S₁ and S₂ includes the first and second output buffers BUF₁ and BUF₂, the first and second precharge circuits PC₁ and PC₂ for precharging the output lines of the output buffers electrically connected with the data lines, and the first switch device SWC₁ for electrically connecting the output lines of the first and second output buffers BUF₁ and BUF₂.

In FIG. 10, the precharge switch device SWP₁ is omitted from the precharge circuit shown in FIG. 4, and the first switch device SWC₁ is used by the first and second output buffers BUF₁ and BUF₂. The means for supplying the high-potential-side power supply voltage VDDHS and the means for supplying the low-potential-side power supply voltage VSS are merely provided to the output line of each output buffer.

A common precharge voltage PV can be generated in units of two output buffers by utilizing a parasitic capacitor such as a wiring capacitor of the data line of the display panel 512. The precharge operation shown in FIG. 7 is performed using the precharge voltage PV.

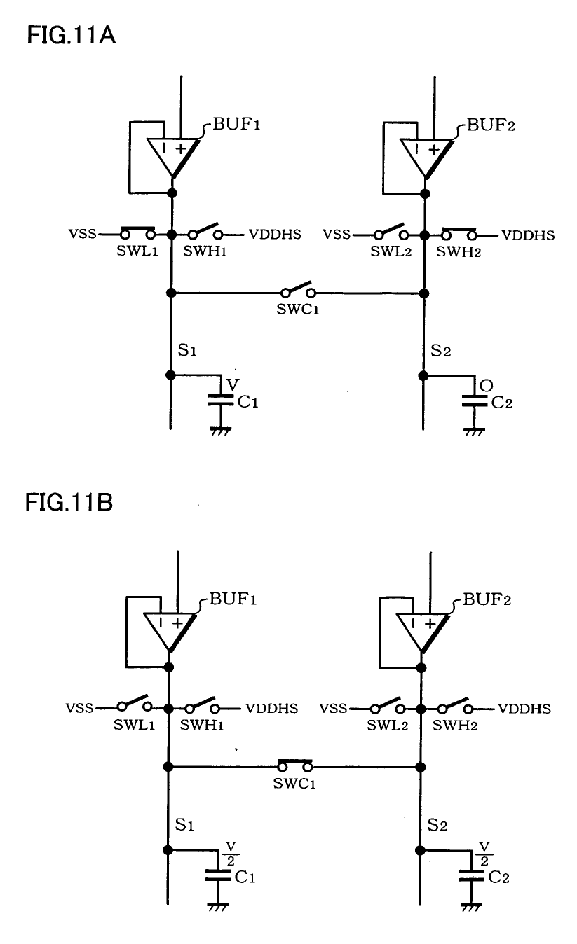

FIGS. 11A and 11B are diagrams illustrative of the operation for generating the precharge voltage PV in FIG. 10.

FIGS. 11A and 11B illustrate the case where the precharge voltage PV is generated for the first and second output buffers BUF₁ and BUF₂. Note that the precharge voltage PV can be generated for other groups in the same manner as described below.

In each drive period, the precharge voltage is generated according to the procedure shown in FIGS. 11A and 11B in the first precharge period PT1 or before the first precharge period PT1.

A state in which the precharge switch devices SWL₁, SWL₂, SWH₁, and SWH₂ and the first switch device SWC₁ are set in a nonconducting state transitions to the state shown in FIG. 11A.

In FIG. 11A, the high-potential-side power supply voltage VDDHS is supplied to the output line of one of the first and second output buffers BUF₁ and BUF₂ in the first precharge period PT1 in the horizontal scan period 1H (drive period), and the low-potential-side power supply voltage VSS is supplied to the output line of the other output buffer. Therefore, one of the first and second precharge circuits PC₁ and PC₂ supplies the high-potential-side power supply voltage VDDHS to the output line of one of the first and second output buffers BUF₁ and BUF₂, and the remaining precharge circuit supplies the low-potential-side power supply voltage VSS to the output line of the other of the first and second output buffers BUF₁ and BUF₂. In FIG 11A, one of the precharge switch devices SWH₁ and SWH₂ connected with the output lines of the first and second output buffers BUF₁ and BUF₂ is set in a conducting state, and one of the precharge switch devices SWL₁ and SWL₂ connected with the output line of the other output buffer is set in a conducting state. Therefore, the high-potential-side power supply voltage VDDHS or the low-potential-side power supply voltage VSS is supplied to the output line of each output buffer.

As a result, the high-potential-side power supply voltage VDDHS or the low-potential-side power supply voltage VSS of the first and second output buffers BUF₁ and BUF₂ is supplied to the data lines S₁ and S₂ of the display panel 512 connected with the first and second output buffers BUF₁ and BUF₂. An electric charge corresponding to the voltage supplied to each data line is stored in a parasitic capacitor such as a wiring capacitor of each data line. In FIG. 11A, an electric charge corresponding to the voltage V is stored in the parasitic capacitor C₁ of the data line S₁, and a voltage of 0 V is applied to the parasitic capacitor C₂ of the data line S₂.

Then, the precharge switch devices SWH₁, SWH₂, SWL₁, and SWL₂ connected with the first and second output buffers BUF₁ and BUF₂ are set in a nonconducting state, and the first switch device SWC₁ is set in a conducting state from a nonconducting state. As a result, the output lines (data lines S₁ and S₂) of the first and second output buffers BUF₁ and BUF₂ are electrically connected. This causes the electric charge stored in the data lines S₁ and S₂ to be divided between the data lines. Therefore, each data line is set at a voltage corresponding to the amount of electric charge divided and stored in the parasitic capacitor, and a voltage half the potential difference between the high-potential-side power supply voltage VDDHS and the low-potential-side power supply voltage VSS is used as the precharge voltage PV.

Then, the precharge switch devices SWH₁, SWH₂, SWL₁, and SWL₂ and the first switch device SWC₁ are set in a nonconducting state, and the precharge operation corresponding to the higher-order two-bit data of the grayscale data is performed as described above using the voltage of the data line as the precharge voltage PV.

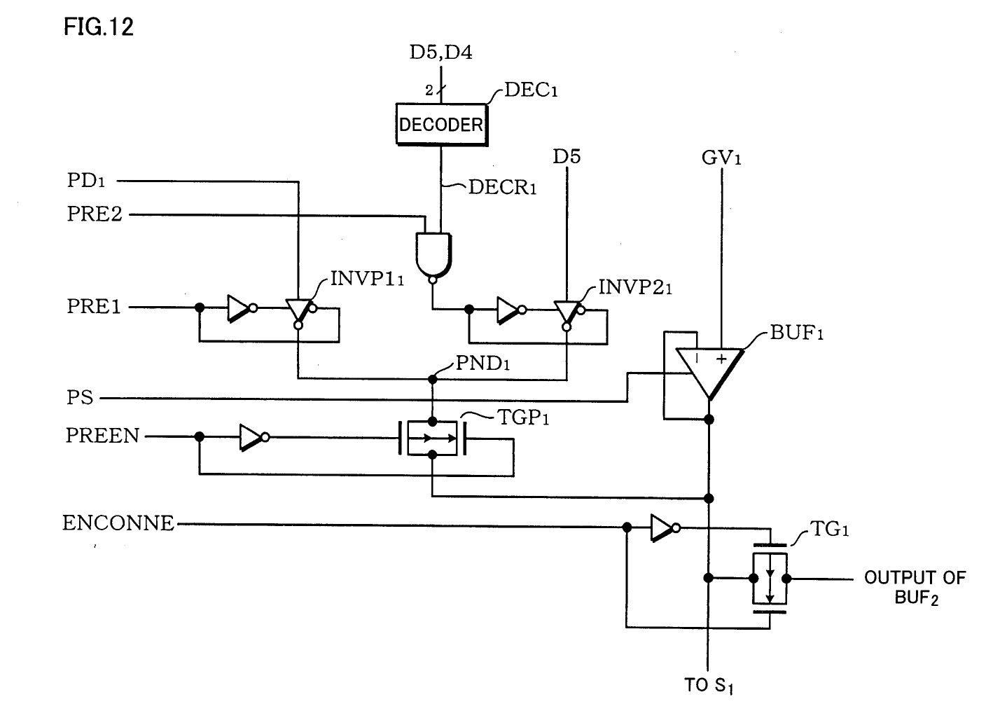

FIG. 12 is a circuit diagram of a configuration example of the first precharge circuit PC₁ which realizes the precharge operation shown in FIGS. 10, 11A, and 11B.

FIG. 12 also shows a means for realizing the function of the first switch device SWC₁ used by the first precharge circuit PC₁ and the second precharge circuit PC₂. In FIG. 12, the power supply voltages of the first precharge circuit PC₁ are the same as those of the first output buffer BUF₁. Although FIG. 12 illustrates a configuration example of the first precharge circuit PC₁, other precharge circuits can be configured in the same manner as the first precharge circuit PC₁.

The operating current of the first output buffer BUF₁ is stopped or limited using a power save control signal PS, whereby the output is set in a high impedance state. In more detail, the output of the first output buffer BUF₁ is set in a high impedance state when the power save control signal PS is set at the H level, and the first output buffer BUF₁ drives the output line based on the grayscale voltage when the power save control signal PS is set at the L level.

A transmission gate TG₁ provided between the output line of the first output buffer BUF₁ and the output line of the second output buffer BUF₂ is connected with the output line of the first output buffer BUF₁. The transmission gate TG₁ realizes the function of the first switch device SWC₁ shown in FIG. 8. The transmission gate TG₁ electrically connects the output lines of the first and second output buffers BUF₁ and BUF₂ when a connection control signal ENCONNE is set at the H level, and electrically disconnects the output lines of the first and second output buffers BUF₁ and BUF₂ when the connection control signal ENCONNE is set at the L level.

A transmission gate TGP₁ for supplying the precharge voltage for the first and second precharge periods PT1 and PT2 is connected with the output line of the first output buffer BUF₁. The precharge voltage for the first and second precharge periods PT1 and PT2 is the voltage of a precharge voltage output node PND₁. The transmission gate TGP₁ electrically connects the precharge voltage output node PND₁ and the output line of the first output buffer BUF₁ when a precharge control signal PREEN is set at the H level, and electrically disconnects the precharge voltage output node PND₁ and the output line of the first output buffer BUF₁ when the precharge control signal PREEN is set at the L level.

A grayscale voltage GV₁ from the DAC 528 shown in FIG. 2 is supplied to the first output buffer BUF₁. The DAC 528 outputs the grayscale voltage GV₁ corresponding to six-bit grayscale data D5 to D0 (MSB is D5) corresponding to the data line S₁ based on the grayscale data. The most-significant-bit data D5 of the grayscale data is input to the first precharge circuit PC₁ for the second precharge period PT2. The higher-order two-bit data D5 and D4 of the grayscale data is input to a decoder DEC₁. The decoder DEC₁ is provided in the output stage of the DAC 528 or provided inside the first precharge circuit PC₁, for example. The decoder DEC₁ outputs a decode result signal DECR₁ set at the H level when the higher-order two-bit data D5 and D4 of the grayscale data is “00” or “11”, otherwise the decoder DEC₁ outputs the decode result signal DECR₁ set at the L level.

The control section (precharge control circuit) (not shown) includes a control register which designates whether to set the data line at the high-potential-side power supply voltage VDDHS or at the low-potential-side power supply voltage VSS for generating the precharge voltage PV in the first precharge period PT1. The high-potential-side power supply voltage VDDHS or the low-potential-side power supply voltage VSS can be designated in data line units using designation data. Designation data PD₁ is input to the first precharge circuit PC₁. In FIG. 12, the designation data PD₁ is set at the L level when setting the data line at the high-potential-side power supply voltage VDDHS, and set at the H level when setting the data line at the low-potential-side power supply voltage VSS. In the examples shown in FIGS. 10, 11A, and 11B, the designation data PD₁ for the data line S₁ is set at the L level, and the designation data PD₂ for the data line S₂ is set at the H level.

The outputs of inverters INVP1₁ and INVP2₁ are connected with the precharge voltage output node PND₁.

The designation data PD₁ is input to the input of the inverter INVP1₁. The inverter INVP1₁ outputs inversion data of the designation data PD₁ when a precharge control signal PRE1 is set at the H level. Therefore, the voltage of the precharge voltage output node PND₁ is set at the high-potential-side power supply voltage VDDHS when the inverter INVP1₁ outputs the signal at the H level, and the voltage of the precharge voltage output node PND₁ is set at the low-potential-side power supply voltage VSS when the inverter INVP1₁ outputs the signal at the L level. The inverter INVP1₁ sets the output in a high impedance state when the precharge control signal PRE1 is set at the L level.

The most-significant-bit data D5 of the grayscale data is input to the input of the inverter INVP2₁. The inverter INVP2₁ outputs inversion data of the data D5 when a mask result signal obtained by masking the decode result signal DECR₁ with a precharge control signal PRE2 is set at the H level. Therefore, the voltage of the precharge voltage output node PND₁ is set at the high-potential-side power supply voltage VDDHS when the inverter INVP2₁ outputs the signal at the H level, and the voltage of the precharge voltage output node PND₁ is set at the low-potential-side power supply voltage VSS when the inverter INVP2₁ outputs the signal at the L level. The inverter INVP2₁ sets the output in a high impedance state when the mask result signal is set at the L level.

The control section (precharge control circuit) (not shown) supplies the precharge control signals PREEN, PRE1, and PRE2, the connection control signal ENCONNE, and the power save control signal PS to the first to Pth precharge circuits PC₁ to PC_{P}.

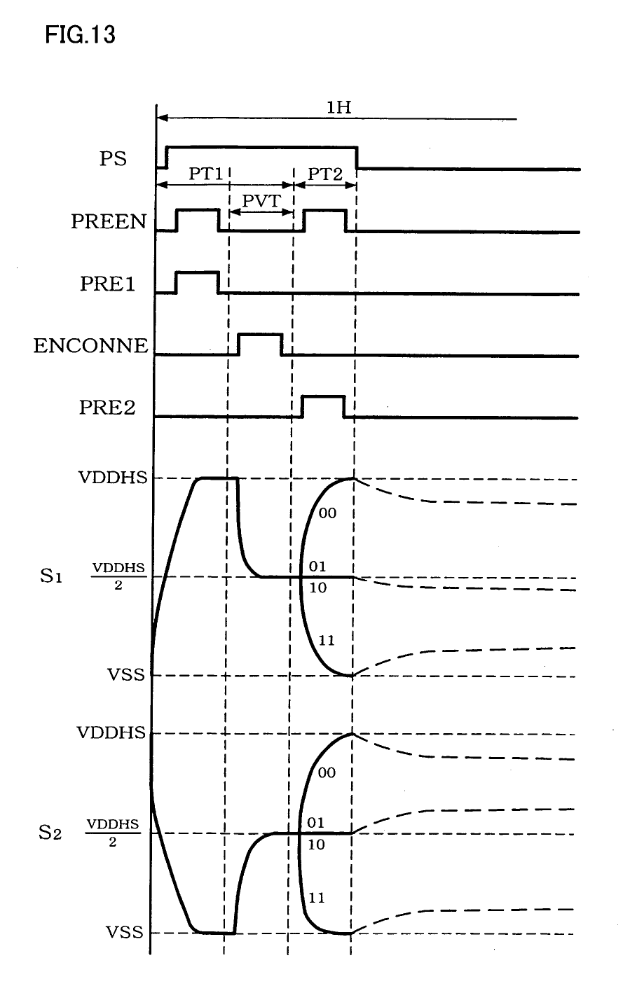

FIG. 13 is a timing diagram of an operation example of the circuit diagram shown in FIG. 12.

In FIG. 13, the designation data PD₁ is set at the L level, and the designation data PD₂ is set at the H level.

When the horizontal scan period 1H (drive period) has been started, the power save control signal PS is set at the H level in order to perform the precharge operation. The output of the first output buffer BUF₁ is set in a high impedance state when the power save control signal PS is set at the H level. In this case, the precharge control signals PREEN, PRE1, and PRE2 and the connection control signal ENCONNE are set at the L level.

The first precharge period PT1 is then started. In the first precharge period PT1, the precharge control signals PREEN and PRE1 are changed from the L level to the H level. Therefore, since the output from the inverter INVP1₁ is set at the H level, the precharge voltage output node PND₁ is set at the high-potential-side power supply voltage VDDHS. The voltage of the precharge voltage output node PND₁ is supplied to the data line S₁ through the transmission gate TGP₁ (PT1).

Likewise, since the output from the inverter INVP2₁ is set at the L level, the precharge voltage output node PND₂ is set at the low-potential-side power supply voltage VSS in the first precharge period PT1. The voltage of the precharge voltage output node PND₂ is supplied to the data line S₂ through the transmission gate TGP₂ (PT1).

In a precharge voltage generation period PVT in the first precharge period PT1, the precharge control signals PREEN and PRE1 are set at the L level and the connection control signal ENCONNE is changed from the L level to the H level. As a result, the data lines S₁ and S₂ (output lines of the first and second output buffers BUF₁ and BUF₂) are electrically connected through the transmission gate TG₁, whereby the voltages of the data lines S₁ and S₂ (output lines of the first and second output buffers BUF₁ and BUF₂) are set at “VDDHS/2” (PVT). In this example, the low-potential-side power supply voltage VSS is 0 V.

In the second precharge period PT2 after the first precharge period PT1, the connection control signal ENCONNE is set at the L level, and the precharge control signals PREEN and PRE2 are changed from the L level to the H level. Therefore, the precharge voltage output node PND1 is electrically connected with the output of the inverter INVP2₁ and set at a voltage corresponding to the decode result signal DECR₁.

Specifically, when the higher-order two-bit data D5 and D4 of the grayscale data is “00”, the decode result signal DECR₁ is set at the H level. Since the most-significant-bit data D5 of the grayscale data is “0”, the output from the inverter INVP2₁ is set at the H level, whereby the high-potential-side power supply voltage VDDHS is supplied to the precharge voltage output node PND₁. As a result, the data line S₁ is precharged to the high-potential-side power supply voltage VDDHS through the transmission gate TGP₁.

The decode result signal DECR₁ is set at the L level when the higher-order two-bit data D5 and D4 of the grayscale data is “01”. Therefore, since the output of the inverter INVP2₁ is set in a high impedance state, the voltage of the precharge voltage output node PND₁ remains at the voltage in the first precharge period PT1. As a result, the data line S₁ is precharged to the voltage “VDDHS/2” through the transmission gate TGP₁.

The decode result signal DECR₁ is set at the L level when the higher-order two-bit data D5 and D4 of the grayscale data is “10”. Therefore, since the output of the inverter INVP2₁ is set in a high impedance state, the voltage of the precharge voltage output node PND₁ remains at the voltage in the first precharge period PT1. As a result, the data line S₁ is precharged to the voltage “VDDHS/2” through the transmission gate TGP₁.

The decode result signal DECR₁ is set at the H level when the higher-order two-bit data D5 and D4 of the grayscale data is “11”. Since the most-significant-bit data D5 of the grayscale data is “1”, the output from the inverter INVP2₁ is set at the L level, whereby the low-potential-side power supply voltage VSS is supplied to the precharge voltage output node PND₁. As a result, the data line S₁ is precharged to the low-potential-side power supply voltage VSS through the transmission gate TGP₁.

The power save control signal PS is set at the L level after the second precharge period PT2, and the first and second output buffers BUF₁ and BUF₂ drive the data lines S₁ and S₂ based on the grayscale voltages GV₁ and GV₂.

As described above, since the data line is precharged to the high-potential-side power supply voltage VDDHS, the voltage “VDDHS/2”, or the low-potential-side power supply voltage VSS corresponding to the grayscale data in the second precharge period PT2, the potential difference driven by the output buffer after the precharge operation is reduced, as shown in FIG. 7. This reduces the amount of electric charge which must be charged/discharged, whereby the power consumption of the output buffer can be reduced. Moreover, since the charge/discharge time is also reduced, the current consumption of the output buffer can be reduced.

Since the output buffer is provided in data line units, one of the three precharge voltages can be selected corresponding to the grayscale data in data line units. Therefore, power consumption can be optimally reduced in output buffer units. Therefore, the effect of reducing the total power consumption is increased in comparison with the case of uniformly reducing the power consumption of each output buffer.

3. Electronic Instrument

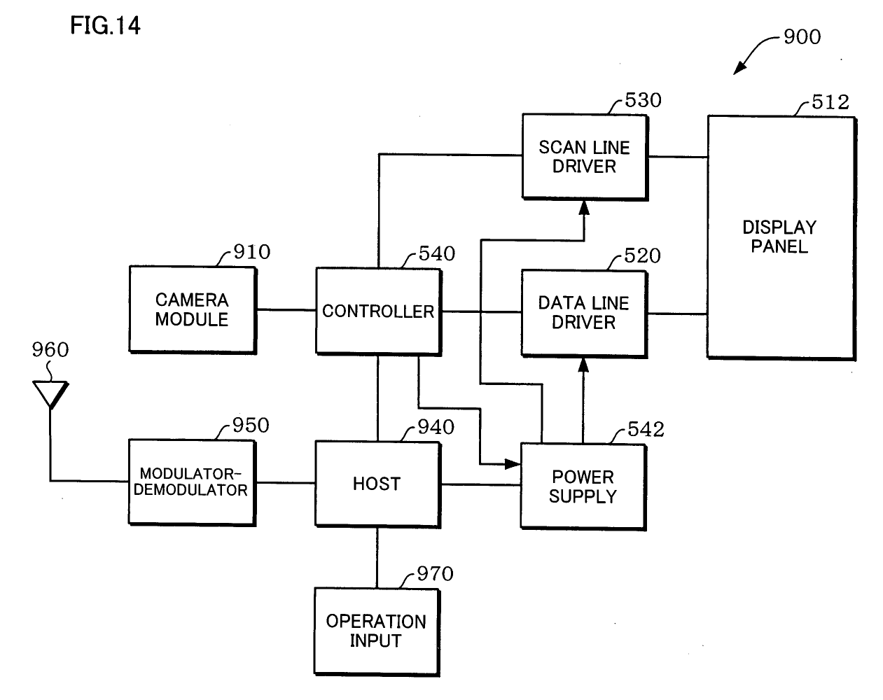

FIG. 14 is a block diagram of a configuration example of an electronic instrument according to one embodiment of the invention. FIG. 14 is a block diagram of a configuration example of a portable telephone as an example of the electronic instrument. In FIG. 14, the sections as shown in FIG. 1 are indicated by the same symbols. Description of these sections is appropriately omitted.

A portable telephone 900 includes a camera module 910. The camera module 910 includes a CCD camera, and supplies data of an image captured using the CCD camera to the controller 540 in a YUV format.

The portable telephone 900 includes the display panel 512. The display panel 512 is driven by the data line driver circuit 520 and the scan line driver circuit 530. The display panel 512 includes scan lines, data lines, and pixels.

The controller 540 is connected with the data line driver circuit 520 and the scan line driver circuit 530, and supplies grayscale data in an RGB format to the data line driver circuit 520.

The power supply circuit 542 is connected with the data line driver circuit 520 and the scan line driver circuit 530, and supplies drive power supply voltage to each driver circuit. The power supply circuit 542 supplies the common electrode voltage to the common electrode VCOM of the display panel 512.

A host 940 is connected with the controller 540. The host 940 controls the controller 540. The host 940 demodulates grayscale data received through an antenna 960 using a modulator-demodulator section 950, and supplies the demodulated grayscale data to the controller 540. The controller 540 causes the data line driver circuit 520 and the scan line driver circuit 530 to display an image on the display panel 512 based on the grayscale data.

The host 940 modulates display data generated by the camera module 910 using the modulator-demodulator section 950, and directs transmission of the modulated data to another communication device through the antenna 960.

The host 940 transmits and receives display data, images using the camera module 910, and displays an image on the display panel 512 based on operational information from an operation input section 970.

The invention is not limited to the above-described embodiments. Various modifications and variations may be made within the spirit and scope of the invention. For example, the invention may be applied not only to drive the above-described liquid crystal display panel, but also to drive an electroluminescent or plasma display device.

Some of the requirements of any claim of the invention may be omitted from a dependent claim which depends on that claim. Moreover, some of the requirements of any independent claim of the invention may be allowed to depend on any other independent claim.

Although only some embodiments of the invention are described in detail above, those skilled in the art would readily appreciate that many modifications are possible in the embodiments without materially departing from the novel teachings and advantages of the invention. Accordingly, such modifications are intended to be included within the scope of the invention.

What is claimed is:

1. A driver circuit for driving a data line of an electro-optical device, the driver circuit comprising:
an output buffer which drives the data line based on grayscale data; and
a precharge circuit which precharges an output line of the output buffer electrically connected with the data line;
the precharge circuit supplying a first precharge voltage between a high-potential-side power supply voltage and a low-potential-side power supply voltage of the output buffer to the output line in a first precharge period in a drive period;
the precharge circuit supplying the high-potential-side power supply voltage of the output buffer, the low-potential-side power supply voltage of the output buffer, or the first precharge voltage to the output line based on higher-order two-bit data of the grayscale data in a second precharge period after the first precharge period; and
the output buffer driving the output line based on a grayscale voltage corresponding to the grayscale data after the second precharge period.

2. The driver circuit as defined in claim 1, wherein the first precharge voltage is generated as an average value using the voltage to which the output line of the output buffer is precharged and a precharge voltage to which an output line of an output buffer other than the output buffer is precharged.

3. A driver circuit for driving data lines of an electro-optical device, the driver circuit comprising:
first to Pth (P is an integer of two or more) output buffers which drive the data lines based on grayscale data;
first to Pth precharge circuits which precharge output lines of the output buffers electrically connected with the data lines; and
first to (P-1)th switch devices which electrically connect the output lines of the first to Pth output buffers;
the first to Pth precharge circuits precharging the output lines of the first to Pth output buffers by electrically connecting the output lines of the first to Pth output buffers through the first to (P-1)th switch devices, and the first to Pth output buffers then driving the data lines based on the grayscale data.

4. The driver circuit as defined in claim 3,
wherein, in a first precharge period in a drive period, at least one of the first to Pth precharge circuits supplies a high-potential-side power supply voltage of the first to Pth output buffers to the output line of the output buffer, the remaining precharge circuits supply a low-potential-side power supply voltage of the first to Pth output buffers to the output lines of the output buffers, and the first to (P-1)th switch devices are then set in a conducting state to set voltages of the output lines of the first to Pth output buffers at a first precharge voltage;
wherein, in a second precharge period after the first precharge period, the first to Pth precharge circuits supply the high-potential-side power supply voltage, the low-potential-side power supply voltage, or the first precharge voltage to the output lines of the first to Pth output buffers based on higher-order two-bit data of the grayscale data; and
wherein the first to Pth output buffers drive the output lines based on the grayscale data after the second precharge period.

5. An electro-optical device comprising:
a plurality of scan lines;
a plurality of data lines;
a plurality of pixels;
a scan line driver circuit which scans the scan lines; and
the driver circuit as defined in claim 1 which drives the data lines.

6. An electro-optical device comprising:
a plurality of scan lines;
a plurality of data lines;
a plurality of pixels;
a scan line driver circuit which scans the scan lines; and
the driver circuit as defined in claim 3 which drives the data lines.

7. An electronic instrument comprising the electro-optical device as defined in claim 5.

8. An electronic instrument comprising the electro-optical device as defined in claim 6.

9. A drive method for driving a data line of an electro-optical device, the method comprising:
supplying a first precharge voltage to an output line of an output buffer for driving the data line in a first precharge period in a drive period;
supplying a high-potential-side power supply voltage of the output buffer, a low-potential-side power supply voltage of the output buffer, or the first precharge voltage to the output line based on higher-order two-bit data of grayscale data in a second precharge period after the first precharge period; and
causing the output buffer to drive the output line based on a grayscale voltage corresponding to the grayscale data after the second precharge period.

10. A drive method for driving a driver circuit including first to Pth (P is an integer of two or more) output buffers which drive data lines of an electro-optical device based on grayscale data, first to Pth precharge circuits which precharge output lines of the output buffers electrically connected with the data lines, and first to (P-1)th switch devices which electrically connect the output lines of the first to Pth output buffers, the method comprising:
in a first precharge period in a drive period, causing at least one of the first to Pth precharge circuits to supply a high-potential-side power supply voltage of the first to Pth output buffers to the output line of the output buffer, causing the remaining precharge circuits to supply a low-potential-side power supply voltage of the first to Pth output buffers to the output lines of the output buffers, and then setting the first to (P-1)th switch devices in a conducting state to set voltages of the output lines of the first to Pth output buffers at a first precharge voltage;
in a second precharge period after the first precharge period, causing the first to Pth precharge circuits to supply the high-potential-side power supply voltage, the low-potential-side power supply voltage, or the first precharge voltage to the output lines of the first to Pth output buffers based on higher-order two-bit data of the grayscale data; and
causing the first to Pth output buffers to drive the output lines based on the grayscale data after the second precharge period.
